(19) United States
(12) Patent Application Publication
(10) Pub. No.: US 2016/0013323 A1
(43) Pub. Date: Jan. 14, 2016

(54) THIN FILM TRANSISTOR SUBSTRATE, DISPLAY APPARATUS, METHOD FOR MANUFACTURING THE THIN FILM TRANSISTOR SUBSTRATE, AND METHOD FOR MANUFACTURING THE DISPLAY APPARATUS

(71) Applicant: SAMSUNG DISPLAY CO., LTD., Yongin-City (KR)

(72) Inventors: Woonghee JEONG, Yongin-City (KR); Yoonho KHANG, Yongin-City (KR); Myounghwa KIM, Yongin-City (KR); Youngki SHIN, Yongin-City (KR); Kyoungwon LEE, Yongin-City (KR)

(21) Appl. No.: 14/565,880

(22) Filed: Dec. 10, 2014

(30) Foreign Application Priority Data
Jul. 8, 2014 (KR) 10-2014-0085365

(51) Int. Cl. H01L 29/786; H01L 27/12; H01L 29/66

(52) U.S. Cl. CPC H01L 29/78603; H01L 29/78675; H01L 29/66757; H01L 27/1274; H01L 27/1222

(57) ABSTRACT

A thin film transistor substrate includes a substrate, an anodized aluminum layer on the substrate, a polycrystalline silicon layer covering the anodized aluminum layer, and an insulating layer covering the polycrystalline silicon layer.

### CROSS-REFERENCE TO RELATED APPLICATION

Korean Patent Application No. 10-2014-0085365, filed on Jul. 8, 2014, in the Korean Intellectual Property Office, and, entitled: “Thin Film Transistor Substrate, Display Apparatus, Method for Manufacturing the Thin Film Transistor Substrate, and Method for Manufacturing the Display Apparatus,” is incorporated by reference herein in its entirety.

### BACKGROUND

1. Field

One or more embodiments relate to a thin film transistor substrate, a display apparatus, a method for manufacturing the thin film transistor, and a method for manufacturing the display apparatus.

2. Description of the Related Art

In general, thin film transistors (TFTs) are mounted on a substrate to control operation of (sub) pixels in display apparatuses such as organic light-emitting display apparatuses. The TFT includes a semiconductor layer, a source electrode, a drain electrode, and a gate electrode. The semiconductor layer typically includes polycrystalline silicon obtained by crystallizing amorphous silicon.

### SUMMARY

Embodiments are directed to a thin film transistor substrate including a substrate, an anodized aluminum layer on the substrate, a polycrystalline silicon layer covering the anodized aluminum layer, and an insulating layer covering the polycrystalline silicon layer.

The anodized aluminum layer may include a plurality of holes that extend in a direction perpendicular to the substrate.

The plurality of holes of the anodized aluminum layer may be filled with air.

The insulating layer may include a plurality of through holes that expose the polycrystalline silicon layer. The thin film transistor substrate may further include a source electrode and a drain electrode that contact the polycrystalline silicon layer via the through holes.

The anodized aluminum layer may correspond to a source region, a drain region, and an active region of the polycrystalline silicon layer. The source region and the drain region may contact the source electrode and the drain electrode, and the active region may be between the source region and the drain region.

The anodized aluminum layer may correspond to an active region of the polycrystalline silicon layer between a source region and a drain region of the polycrystalline silicon layer. The source region and the drain region may contact the source electrode and the drain electrode.

The thin film transistor substrate may further include an auxiliary buffer layer covering the anodized aluminum layer. The polycrystalline silicon layer may be provided on the auxiliary buffer layer.

Embodiments are also directed to a display apparatus including a substrate, an anodized aluminum layer on the substrate, a polycrystalline silicon layer covering the anodized aluminum layer, an insulating layer covering the polycrystalline silicon layer, the insulating layer including a plurality of through holes to expose the polycrystalline silicon layer, a source electrode and a drain electrode contacting the polycrystalline silicon layer via the through holes, and a pixel electrode electrically connected to any one of the source electrode and the drain electrode.

The anodized aluminum layer may include a plurality of holes that extend in a direction perpendicular to the substrate.

The plurality of holes of the anodized aluminum layer may be filled with air.

The anodized aluminum layer may correspond to a source region, a drain region, and an active region of the polycrystalline silicon layer. The source region and drain region may contact the source electrode and the drain electrode, and the active region may be between the source region and the drain region.

The anodized aluminum layer may correspond to an active region of the polycrystalline silicon layer between a source region and a drain region of the polycrystalline silicon layer. The source region and the drain region may contact the source electrode and the drain electrode.

The display apparatus may further include an auxiliary buffer layer covering the anodized aluminum layer. The polycrystalline silicon layer may be on the auxiliary buffer layer.

Embodiments are also directed to a method for manufacturing a thin film transistor substrate including forming an aluminum layer on a substrate, forming an anodized aluminum layer by anodizing the aluminum layer, forming an amorphous silicon layer to cover the anodized aluminum layer, and forming a polycrystalline silicon layer by crystallizing the amorphous silicon layer.

In forming the anodized aluminum layer, a plurality of holes extending in a direction perpendicular to the substrate may be formed in the anodized aluminum layer.

The method may further include forming an auxiliary buffer layer covering the anodized aluminum layer. In forming the amorphous silicon layer to cover the anodized aluminum layer, the amorphous silicon layer is formed on the auxiliary buffer layer.

In forming the aluminum layer, the aluminum layer may be patterned to correspond to a thin film transistor.

The method may further include patterning the anodized aluminum layer to correspond to a thin film transistor.

Embodiments are also directed to a method of manufacturing a display apparatus including manufacturing a thin film transistor substrate as described above and forming a pixel electrode electrically connected to a polycrystalline silicon layer.

### BRIEF DESCRIPTION OF THE DRAWINGS

Features will become apparent to those of skill in the art by describing in detail exemplary embodiments with reference to the attached drawings in which:

FIGS. 1 to 5 illustrate cross-sectional views schematically depicting stages of a manufacturing process for manufacturing a thin film transistor substrate according to an embodiment; and

FIG. 6 illustrates a cross-sectional view schematically depicting an organic light-emitting display apparatus according to an embodiment.

FIG. 7 illustrates a cross-sectional view schematically depicting an organic light-emitting display apparatus according to another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

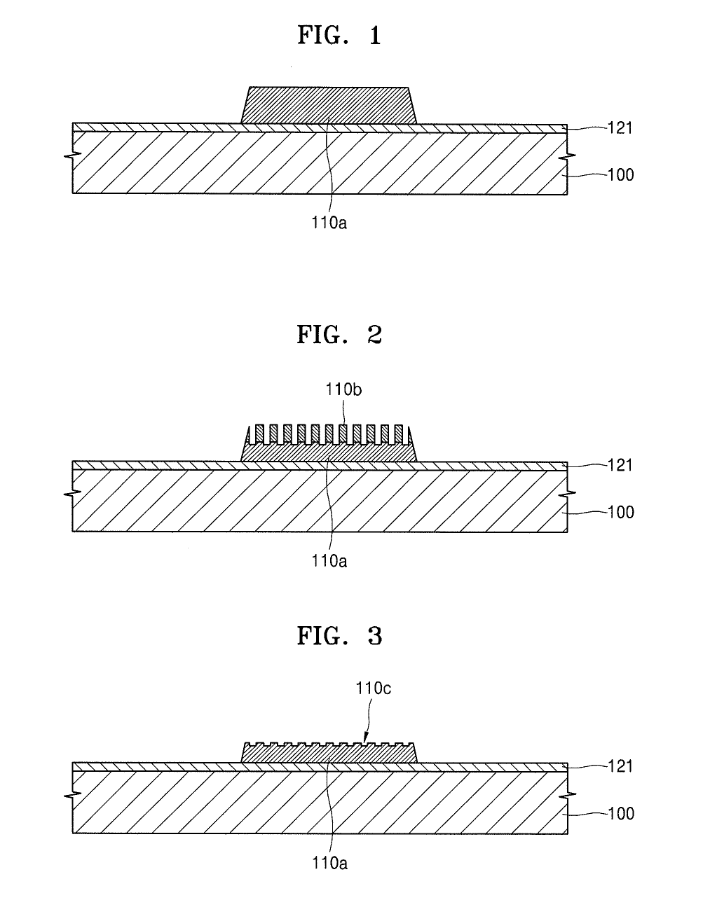

As used herein, the terms “correspond” or “corresponding” may refer generally to being in an overlapping relationship, for example, overlapping or being aligned in a vertical direction, with reference to FIGS. 1 to 5.

FIGS. 1 to 5 are cross-sectional views schematically depicting stages of a manufacturing process for manufacturing a thin film transistor (TFT) substrate according to an embodiment.

In a method for manufacturing a TFT substrate according to the present embodiment, a substrate 100, for example, a base substrate, may be prepared. The substrate 100 may be formed of a suitable material, for example, a glass material, a metal material, or a plastic material such as polyethylene terephthalate (PET), polyethylene naphthalate (PEN), or polyimide.

After the substrate 100 is prepared, as illustrated in FIG. 1, an aluminum layer 110a may be formed on the substrate 100. Prior to the forming of the aluminum layer 110a on the substrate 100, a buffer layer 121 of a material such as silicon oxide or silicon oxynitride may be formed on the substrate 100, and then, the aluminum layer 110a may be formed on the buffer layer 121. The buffer layer 121 may prevent the intrusion of impurities into an amorphous silicon layer that will be subsequently formed, as described below, or into a polycrystalline silicon layer obtained by crystallizing the amorphous silicon layer. For example, an organic insulating material such as polyethylene terephthalate (PET), polyethylene naphthalate (PEN), polyacrylate, or polyimide may be used as a material for forming the buffer layer 121. The aluminum layer 110a may be formed by, for example, a deposition method.

The aluminum layer 110a may be anodized. A process of anodizing the aluminum layer 110a may be performed by a suitable method to form an anodized aluminum layer 110. By oxidizing the aluminum layer 110a, a plurality of holes 110h extending perpendicularly to the substrate 100 may be formed, as illustrated in FIG. 4. A method of forming the anodized aluminum layer 110 is described below.

After the aluminum layer 110a is formed as illustrated in FIG. 1, a first anodizing process may be performed. For example, the aluminum layer 110a may be dipped in oxalic acid at 10° C. and maintained in a state in which a voltage of about 40˜50 V is applied thereto for about 500˜600 seconds. As illustrated in FIG. 2, a first hole layer 110b may be formed in a part of the aluminum layer 110a. As illustrated in FIG. 3, the first hole layer 110b may be removed. For example, the first hole layer 110b may be removed by using phosphoric acid, chromic acid, or a mixture thereof. As illustrated in FIG. 3, the aluminum layer 110a may be formed to have an upper surface having a groove 110c. The groove 110c in the upper surface of the aluminum layer 110a may serve as a seed for forming a plurality of holes 110h in a second anodizing process that will be subsequently performed, as described below.

The second anodizing process may be performed on the aluminum layer 110a having the grooves 110c formed in the upper surface thereof. When the second anodizing process is performed under the conditions that are the same as or similar to those of the first anodizing process, the anodized aluminum layer 110 obtained thereby may have holes 110h extending in a direction roughly perpendicular to the substrate 100 as illustrated in FIG. 4.

In some implementations, the anodized aluminum layer may be formed by performing an anodizing process only once, rather than performing a two-step process of the first anodizing process and the second anodizing process. However, in this case, the anodizing process is performed without any seed on an aluminum layer. It may be difficult to form the holes 110h to be uniformly distributed.

In the manufacturing of a TFT substrate as described below, a size of each of the holes 110h and a distance between the holes 110h of the anodized aluminum layer 110 may be adjusted. After forming the anodized aluminum layer 110 in which the holes 110h extend in a direction roughly perpendicular to the substrate 100, as illustrated in FIG. 4, the diameter of each of the holes 110h may be increased using phosphoric acid, chromic acid, or a mixture thereof, or decreased by coating an inner surface of each hole 110h with a metal such as ruthenium (Ru). In the case of coating that is described below, the thickness of coating may be precisely controlled through an atomic layer deposition (ALD) method.

An amorphous silicon layer may be formed to cover the anodized aluminum layer 110. The amorphous silicon layer may be crystallized, thereby forming a polycrystalline silicon layer 130 (refer to FIG. 5). The crystallization of the amorphous silicon layer may be performed, for example, by irradiating an excimer laser beam to the amorphous silicon layer.

When the polycrystalline silicon layer 130 is formed by crystallizing the amorphous silicon layer, the temperature of the amorphous silicon layer may be instantly increased and decreased, during which time the amorphous silicon layer may be in a completely molten state or a near completely melting state and then may be solidified. The amorphous silicon layer may become the polycrystalline silicon layer 130 by polycrystallization in the solidification process. The amount of time consumed in the solidification process, for example, the cooling time, may greatly affect the electrical characteristics of the polycrystalline silicon layer 130. When the cooling time increases, a grain size of the polycrystalline silicon layer 130 may increase, and mobility may increase as well.

In the method for manufacturing the TFT substrate according to the present embodiment, the anodized aluminum layer 110 having the holes 110h may be formed prior to the formation of the amorphous silicon layer. Air may be present in the holes 110h of the anodized aluminum layer 110. Air exhibits superior insulation characteristics. Accordingly, the cooling time during crystallization may be increased and thus the polycrystalline silicon layer 130 having a large grain size and a high mobility may be formed. As described above, the sizes of the holes 110h of the anodized aluminum layer 110 may be easily adjusted by controlling process conditions. The anodized aluminum layer 110 having the holes 110h having an appropriate size so as to optimally form the polycrystalline silicon layer 130 may be easily formed. Accordingly, the TFT substrate having high mobility characteristics may be easily manufactured.

When the anodized aluminum layer 110 includes the holes 110h, it may be difficult to form the amorphous silicon layer uniformly on the anodized aluminum layer 110. When the amorphous silicon layer is formed directly on the anodized aluminum layer 110, step coverage of the anodized aluminum layer 110 may be poor and each of the holes 110h may be partially filled with the amorphous silicon layer. If the amorphous silicon layer is not uniformly formed, the polycrystalline silicon layer 130 obtained by crystallizing the same may not be uniform, and the grain size may not be uniform in the crystallization process.

Accordingly, to improve the formation of the amorphous silicon layer, the present method may further include forming an auxiliary buffer layer 123 to cover the anodized aluminum layer 110. In this case, the amorphous silicon layer may be formed on the auxiliary buffer layer 123. The auxiliary buffer layer 123 may be formed of a material such as silicon oxide or silicon nitride. For example, an organic insulating material such as polyethylene terephthalate (PET), polyethylene naphthalate (PEN), polyacrylate, or polyimide may be used as a material for forming the auxiliary buffer layer 123. The auxiliary buffer layer 123, in addition to the above functions, may perform a function of preventing the intrusion of impurities into the amorphous silicon layer formed thereon or into the polycrystalline silicon layer 130 obtained by crystallizing the amorphous silicon layer.

The anodized aluminum layer 110 may not cover the entire surface of the substrate 100. For example, the aluminum layer 110a may be patterned as illustrated in FIG. 1 to correspond to a TFT to be formed The aluminum layer 110a may be patterned to have the shape as illustrated in FIG. 1, and then, the aluminum layer 110a may be anodized. In other implementations, the aluminum layer 110a may be formed on the entire surface of the substrate 100 and anodized, thereby forming an anodized aluminum layer on the entire surface of the substrate 100. Then, the anodized aluminum layer may be patterned to correspond to the TFT.

An insulating layer 141 may be arranged on the polycrystalline silicon layer 130 to cover the polycrystalline silicon layer 130 as illustrated in FIG. 5. A gate electrode 151 corresponding to the polycrystalline silicon layer 130 may be disposed on the insulating layer 141. The insulating layer 141 may have a plurality of through holes to expose the polycrystalline silicon layer 130. A source electrode 155 and a drain electrode 153 may contact the polycrystalline silicon layer 130 through the through holes. An interlayer insulating layer 143 to insulate the source electrode 155 and the drain electrode 153 from the gate electrode 151 may be interposed between the source electrode 155 and the drain electrode 153, and the gate electrode 151. In this case, the through holes penetrate the insulating layer 141 and the interlayer insulating layer 143.

A portion of the polycrystalline silicon layer 130 contacting the source electrode 155 may be a source region and a portion thereof contacting the drain electrode 153 may be a drain region.

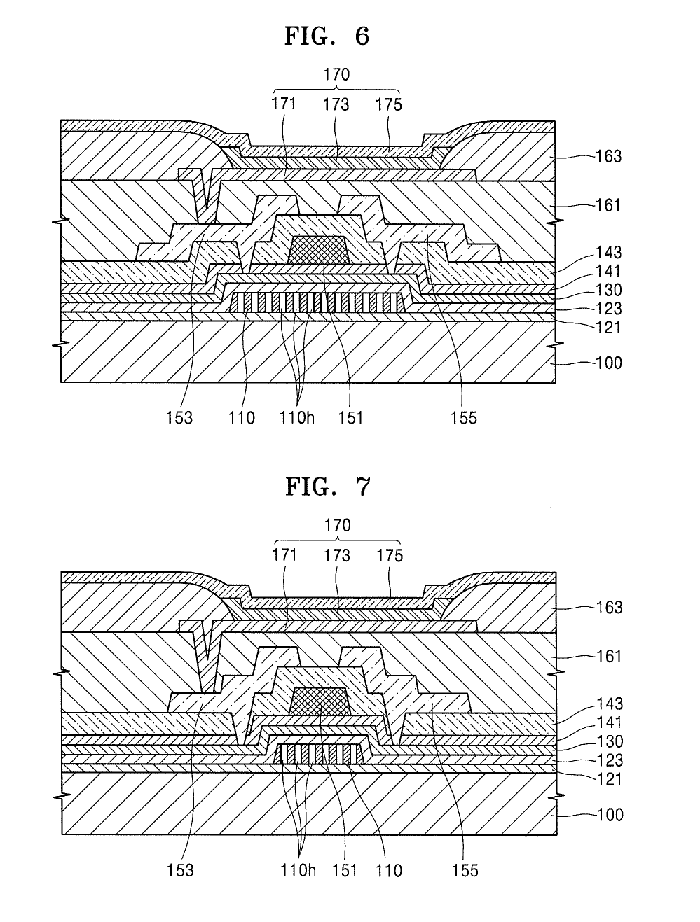

The aluminum layer 110a that is patterned or the anodized aluminum layer 110 that is patterned, as described above, may correspond to the source region, the drain region, and an active region therebetween of the polycrystalline silicon layer 130. Accordingly, the source region, the drain region, and the active region of the polycrystalline silicon layer 130 may be formed to have a large size grain and high mobility. In some implementations, the aluminum layer 110a that is patterned or the anodized aluminum layer 110 that is patterned may correspond to the active region of the polycrystalline silicon layer 130 as shown in FIG. 7, the active region of the polycrystalline silicon layer 130 being a portion that most affects the characteristics of the TFT.

Although FIG. 5 illustrates that the polycrystalline silicon layer 130 corresponds to the entire surface of the substrate 100, as an example, in other implementations, the polycrystalline silicon layer 130 may have an island shape that is patterned for each TFT.

Before the amorphous silicon layer is crystallized into the polycrystalline silicon layer 130, the insulating layer 141 covering the amorphous silicon layer may be formed and then, the amorphous silicon layer may be crystallized. For example, when a laser beam is irradiated onto the insulating layer 141 on the amorphous silicon layer, the amorphous silicon layer may be disposed between the anodized aluminum layer 110 thereunder and the insulating layer 141 thereabove or between the auxiliary buffer layer 123 thereunder and the insulating layer 141 thereabove, thereby increasing the cooling time. The cooling time may be remarkably increased by the presence of anodized aluminum layer 110 under the amorphous silicon layer.

Embodiments also relate to a TFT substrate manufactured by the above-described method.

The TFT substrate according to the present embodiment may have, for example, a shape as illustrated in FIG. 5. The TFT substrate according to the present embodiment may include the substrate 100, the anodized aluminum layer 110, the polycrystalline silicon layer 130, and the insulating layer 141 covering the polycrystalline silicon layer 130. The anodized aluminum layer 110 may have the holes 110h. In particular, the holes 110h may extend in a direction roughly perpendicular to the substrate 100. The anodized aluminum layer 110 having the holes 110h may be formed by forming the aluminum layer and anodizing the aluminum layer as described above. The holes 110h of the anodized aluminum layer 110 may be filled with air. Accordingly, when the amorphous silicon layer is crystallized, the cooling time may be increased, and thus, the grain size of the polycrystalline silicon layer 130 may be increased and the mobility of the polycrystalline silicon layer 130 may be increased.

The insulating layer 141 may have through holes to expose the polycrystalline silicon layer. The source electrode 155 and the drain electrode 153 may contact the polycrystalline silicon layer 130 via the through holes. The interlayer insulating layer 143 to insulate the source electrode 155 and the drain electrode 153 from the gate electrode 151 may be interposed between the source electrode 155 and the drain electrode 153, and the gate electrode 151. The through holes may penetrate the insulating layer 141 and the interlayer insulating layer 143. A portion of the polycrystalline silicon layer 130 contacting the source electrode 155 may be the source region and a portion thereof contacting the drain electrode 153 may be the drain region.

The anodized aluminum layer 110 may correspond to the source region, the drain region, and the active region therebetween of the polycrystalline silicon layer 130. Accordingly, the source region, the drain region, and the active region of the polycrystalline silicon layer 130 may be formed to have a large size grain and high mobility. In some implementations, the anodized aluminum layer 110 may correspond to the active region of the polycrystalline silicon layer 130 as shown in FIG. 7, the active region of the polycrystalline silicon layer 130 being a portion that most affects the characteristics of the TFT.

Although FIG. 5 illustrates that the polycrystalline silicon layer 130 corresponds to the entire surface of the substrate 100, in other implementations, the polycrystalline silicon layer 130 may have an island shape that is patterned for each TFT.

The auxiliary buffer layer 123 may be interposed between the anodized aluminum layer 110 and the polycrystalline silicon layer 130. When the anodized aluminum layer 110 has the holes 110h, it may not be easy to uniformly form the amorphous silicon layer that will become the polycrystalline silicon layer 130 layer, on the anodized aluminum layer 110. According to an implementation, after the auxiliary buffer layer 123 is formed to cover the anodized aluminum layer 110, the amorphous silicon layer that will become the polycrystalline silicon layer 130 may be disposed on the auxiliary buffer layer 123. The auxiliary buffer layer 123 may also prevent intrusion of impurities into the amorphous silicon layer formed thereon or the polycrystalline silicon layer 130 obtained by crystallizing the amorphous silicon layer.

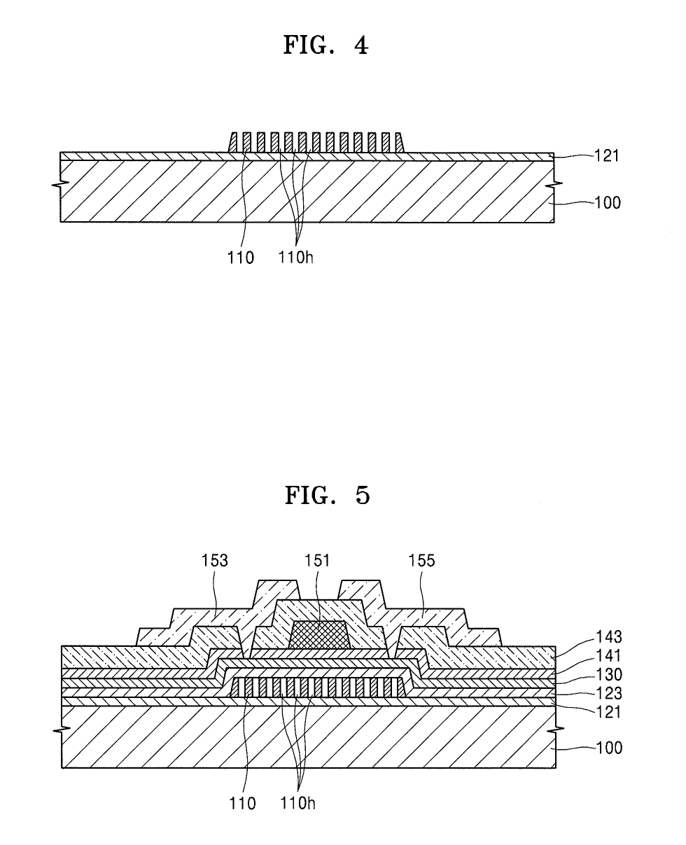

As described above, embodiments are also directed to a display apparatus having the TFT substrate. For example, the display apparatus according to an embodiment may include the above-described TFT substrate and a display device electrically connected to a TFT of the TFT substrate. FIG. 6 is a cross-sectional view schematically illustrating a part of the display apparatus, that is, an organic light-emitting display apparatus, according to an embodiment.

Referring to FIG. 6, the organic light-emitting display apparatus according to the present embodiment may include the substrate 100, a TFT, and an organic light-emitting device 170 that is a display device. The substrate 100 may be formed of a transparent member, for example, a glass member, a plastic member, or a metal member.

The buffer layer 121, the insulating layer 141, and the interlayer insulating layer 143 may be formed on the entire surface of the substrate 100. The TFT may include the anodized aluminum layer 110, the polycrystalline silicon layer 130, the gate electrode 151, the source electrode 155, and the drain electrode 153. The auxiliary buffer layer 123 may be interposed between the anodized aluminum layer 110 and the polycrystalline silicon layer 130.

An insulating layer 161 covering the TFT may be provided. The insulating layer 161 may be a protection layer for protecting the TFT, may be a planarization layer having a flat upper surface, or may have a multilayer structure of the protection layer and the planarization layer. The organic light-emitting device 170, which includes a pixel electrode 171 that is patterned, an opposite electrode 175 roughly corresponding to the entire surface of the substrate 100, and an intermediate layer 173 having a multilayer structure disposed between the pixel electrode 171 and the opposite electrode 175 and including a light-emitting layer, may be formed on the insulating layer 161. In an implementation, intermediate layer 173 may include a partial layer that is a common layer roughly corresponding to the entire surface of the substrate 100 and a patterned layer that is patterned to correspond to the pixel electrode 171. The pixel electrode 171 may be electrically connected to the TFT via a via hole. A pixel definition layer 163 covering an edge of the pixel electrode 171 and having an opening for defining each pixel area may be formed on the insulating layer 161 to roughly correspond to the substrate 100.

The TFT may be manufactured according to the above-described method. The anodized aluminum layer 110 having the holes 110h extending in a direction roughly perpendicular to the substrate 100 may be disposed under the polycrystalline silicon layer 130. Accordingly, the cooling time may be increased when the amorphous silicon layer is crystallized into the polycrystalline silicon layer 130. The grain size and mobility of the polycrystalline silicon layer 130 may be increased, and thus, an organic light-emitting display apparatus having a high quality TFT device may be embodied.

The holes 110h of the anodized aluminum layer 110 may be filled with air. The anodized aluminum layer 110 may be patterned in various shapes. The auxiliary buffer layer 123 may be on the anodized aluminum layer 110. The organic light-emitting display apparatus according to the present embodiment may include the pixel electrode 171 that is electrically connected to any one of the TFT substrates according to the above-described embodiments and modified examples thereof and any one of the source electrode 155 and the drain electrode 153 of the TFT.

Although an organic light-emitting display apparatus is shown as an example, in other implementations, the display apparatus may be another type of display apparatus, for example, a liquid crystal display apparatus.

Embodiments are also directed to a method for manufacturing a display apparatus. A display apparatus such as the organic light-emitting display apparatus may be manufactured by using the above-described TFT substrate manufacturing method and forming the pixel electrode 171 that is electrically connected to the polycrystalline silicon layer 130. To electrically connect the pixel electrode and the polycrystalline silicon layer 130, the pixel electrode 171 may be directly or indirectly connected to the drain electrode 153 and the drain electrode 153 directly or indirectly or indirectly the polycrystalline silicon layer 130.

By way of summation and review, a semiconductor layer of a TFT generally may include polycrystalline silicon obtained by crystallizing amorphous silicon. A laser beam may be irradiated onto an amorphous silicon layer for crystallization. However, such a polycrystalline silicon layer may have low mobility. Increasing the mobility of the polycrystalline silicon layer according to general methods may involve a complicated process and thus manufacturing of the TFT substrate may be difficult.

One or more of the above embodiments provide a TFT substrate that has high mobility characteristics and is easy to manufacture, a display apparatus, a method for manufacturing the TFT, and a method for manufacturing the display apparatus.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made without departing from the spirit and scope thereof as set forth in the following claims.

1. A thin film transistor substrate, comprising:
a substrate;
an anodized aluminum layer on the substrate, the anodized aluminum layer including a plurality of holes that extend in a direction perpendicular to the substrate and penetrate entirely through the anodized aluminum layer to expose an upper surface of a layer beneath the anodized aluminum layer;
a polycrystalline silicon layer covering the anodized aluminum layer; and
an insulating layer covering the polycrystalline silicon layer.

2. (canceled)

3. The thin film transistor substrate as claimed in claim 1, wherein the plurality of holes of the anodized aluminum layer contain air.

4. The thin film transistor substrate as claimed in claim 1, wherein:
the insulating layer includes a plurality of through holes that expose the polycrystalline silicon layer, and
the thin film transistor substrate further includes a source electrode and a drain electrode that contact the polycrystalline silicon layer via the through holes.

5. The thin film transistor substrate as claimed in claim 4, wherein the anodized aluminum layer is limited to a source region, a drain region, and an active region of the polycrystalline silicon layer, the source region and the drain region contacting the source electrode and the drain electrode, and the active region being between the source region and the drain region.

6. The thin film transistor substrate as claimed in claim 4, wherein the anodized aluminum layer is limited to an active region of the polycrystalline silicon layer between a source region and a drain region of the polycrystalline silicon layer, the source region and the drain region contacting the source electrode and the drain electrode.

7. The thin film transistor substrate as claimed in claim 1, further comprising an auxiliary buffer layer covering the anodized aluminum layer, wherein the polycrystalline silicon layer is on the auxiliary buffer layer.

8. A display apparatus, comprising:
a substrate;
an anodized aluminum layer on the substrate, the anodized aluminum layer including a plurality of holes that extend in a direction perpendicular to the substrate and penetrate entirely through the anodized aluminum layer to expose an upper surface of a layer beneath the anodized aluminum layer;
a polycrystalline silicon layer covering the anodized aluminum layer;
an insulating layer covering the polycrystalline silicon layer, the insulating layer including a plurality of through holes to expose the polycrystalline silicon layer;
a source electrode and a drain electrode contacting the polycrystalline silicon layer via the through holes; and
a pixel electrode electrically connected to any one of the source electrode and the drain electrode.

9. (canceled)

10. The display apparatus as claimed in claim 8, wherein the plurality of holes of the anodized aluminum layer contain air.

11. The display apparatus as claimed in claim 8, wherein the anodized aluminum layer is limited to a source region, a drain region, and an active region of the polycrystalline silicon layer, the source region and drain region-contacting the source electrode and the drain electrode, the active region being between the source region and the drain region.

12. The display apparatus as claimed in claim 8, wherein the anodized aluminum layer is limited to an active region of the polycrystalline silicon layer between a source region and a drain region of the polycrystalline silicon layer, the source region and the drain region contacting the source electrode and the drain electrode.

13. The display apparatus as claimed in claim 8, further comprising an auxiliary buffer layer covering the anodized aluminum layer, wherein the polycrystalline silicon layer is on the auxiliary buffer layer.

14. A method for manufacturing a thin film transistor substrate, the method comprising:
forming an aluminum layer on a substrate;
forming an anodized aluminum layer by anodizing the aluminum layer such that a plurality of holes extending in a direction perpendicular to the substrate and penetrating entirely through the anodized aluminum layer to expose an upper surface of a layer beneath the anodized aluminum layer are formed in the anodized aluminum layer;
forming an amorphous silicon layer to cover the anodized aluminum layer; and
forming a polycrystalline silicon layer by crystallizing the amorphous silicon layer.

15. (canceled)

16. The method as claimed in claim 14, further comprising forming an auxiliary buffer layer covering the anodized aluminum layer, wherein, in forming the amorphous silicon layer to cover the anodized aluminum layer, the amorphous silicon layer is formed on the auxiliary buffer layer.

17. The method as claimed in claim 14, wherein, in forming the aluminum layer, the aluminum layer is patterned to be limited to a thin film transistor.

18. The method as claimed in claim 14, further comprising patterning the anodized aluminum layer to be limited to a thin film transistor.
